(19) United States
(12) Patent Application Publication
(10) Pub. No.: US 2002/0089032 A1
(43) Pub. Date: Jul. 11, 2002

(54) PROCESSING METHOD FOR FORMING DISLOCATION-FREE SILICON-ON-INSULATOR SUBSTRATE PREPARED BY IMPLANTATION OF OXYGEN

(76) Inventor: FENG-YI HUANG, STORMVILLE, NY (US)

Correspondence Address: MCGINN & GIBB PC, 1701 CLARENDON BLVD SUITE 100, ARLINGTON, VA, 22209

(21) Appl. No.: 09/379,058

(22) Filed: Aug. 23, 1999

(51) Int. Cl. H01L 29/00

(52) U.S. Cl. 257/507

(57) ABSTRACT

A SIMOX semiconductor structure is provided that may include a silicon substrate, a doped glass layer formed on the silicon substrate by ion implantation and a silicon layer formed on the silicon substrate. Ion implantation may form the doped glass layer to reduce the dislocation density of the silicon layer.

### BACKGROUND OF THE INVENTION

1. Field of the Invention

The present invention generally relates to reducing the dislocation density in silicon-on-insulator (SOI) materials for use in semiconductor applications.

2. Description of the Related Art

Silicon-on-insulator (SOI) substrates prepared by ion implantation are called SIMOX wafers. SIMOX substrates have a thin silicon layer situated on top of a buried oxide formed by oxygen implantation. SIMOX wafers are currently used for advanced SOI CMOS technology. Large amounts of defects in the thin silicon film constitute the main contribution to the yield loss of SOI CMOS. A majority of defects in SIMOX wafers is due to dislocations. Dislocations are detrimental to the fabrication of bipolar devices due to the vertical transport of carriers in a bipolar device. That is, a single dislocation on the active area may result in high leakage and destroy the device.

The dislocation density of SIMOX wafers prepared by conventional methods is on the order of 100,000/cm² or higher, and increases as the thickness of the top silicon film decreases. To further improve the yield of SOI CMOS, and pave the way for potential applications of bipolar devices on SOI, such as SiGe BiCMOS on SOI, the dislocation density has to be further reduced.

A conventional SIMOX wafer preparation procedure uses a bare silicon wafer which is initially implanted with high energy oxygen with certain dosage for a target thickness of buried oxide and a target distance from the top surface. The implanted wafer is then subjected to a high temperature anneal (preferably 1350° C.) which recrystalizes the top silicon layer damaged by the implantation. Before the annealing, the silicon is amorphous, and after the annealing, the dislocation density is about 100,000/cm². One possible source of the dislocations is from the void in the top silicon layer during the implantation. Even at a high temperature anneal, those voids are difficult to relax to a perfect lattice position.

FIG. 1 shows a conventional SOI structure including a silicon substrate 10 on which is formed a buried silicon dioxide layer 12 and a thin silicon film 14. Large amounts of dislocation form in the thin silicon film layer 14 due to the implantation. “Evolution and Future Trends of SIMOX Material” by Steve Krause et al., MRS Bulletin, Dec. 1998, pgs. 25-28, the subject matter of which is incorporated herein by reference, discloses reducing the dislocation density by implantation of two or three incremental doses followed by annealing after each implantation. However, multiple implantations and anneal increase the stacking fault (i.e., another kind of crystal defect that also degrades device performance), the process complexity and the cost.

U.S. Pat. No. 5,661,044, the subject matter of which is incorporated herein by reference, describes a process to implant silicon into the top silicon layer after oxygen implantation so as to fill the voids. This results in a drastic reduction in the dislocation density down to about 1000/cm². The silicon ions relieve the strain which is developed in the top silicon layer during the oxygen implantation without the need for any intervening annealing step.

Another possible source of dislocation is from the interface between the top silicon layer and the buried oxide layer. Because of the strong atomic bonding between the amorphous oxide and silicon, any dislocation generated in the top silicon layer is hard to annihilate even at an annealing temperature of 1350° C. because silicon dioxide has a melting temperature of about 1600° C., and a viscous temperature (i.e., that at which silicon dioxide becomes soft and can re-float) of about 1100° C.

U.S. Pat. No. 5,759,898, the subject matter of which is incorporated herein by reference, discloses a mechanism of transferring strain between two thin films. As illustrated in FIG. 2, a silicon substrate 10 has a buried silicon dioxide layer 12 formed thereon. An extremely thin silicon layer 15 is formed over the buried silicon dioxide layer 12 and has a thickness of 10 nm or less. A SiGe layer 16 is then deposited on the silicon layer 15. Since bulk SiGe alloy has a larger lattice constant as compared to bulk silicon, for a thin film SiGe alloy deposited on a bulk silicon substrate, the SiGe film will be strained to keep the lattice constant fit into that of the silicon substrate. Eventually, dislocation may develop if the strain (or thickness of the SiGe film) exceeds a certain value (the so-called critical thickness). On the other hand, for a SiGe film 16 deposited on a silicon layer 15, the strain accumulated in SiGe during the deposition may be transferred to the underlying thin silicon layer upon anneal at a temperature of 1100° C. or above. The strain created in the silicon layer 15 can further relax to form dislocations, leaving the SiGe layer 16 strain and dislocation free. The thermal anneal is required at an elevated temperature so that the buried oxide layer 12 becomes viscous to allow the silicon to deform.

### SUMMARY OF THE INVENTION

It is, therefore, an object of the present invention to provide a structure that includes a silicon substrate, a doped glass layer formed on the silicon substrate by ion implantation, and a thin silicon layer formed on the top of the doped glass layer. The ion implantation may form the doped glass layer to reduce the dislocation density of the silicon layer. The doped glass layer may include boron silicate glass, and may be formed by ion implantation of oxygen and boron. The doped glass layer may include phosphorous silicate glass, and may be formed by ion implantation of phosphorous and oxygen.

Another object of the present invention is to provide a method of forming a SIMOX semiconductor structure. The method may include providing a silicon substrate, forming a silicon layer over the buried oxide layer, and decreasing the dislocation density of the silicon layer by implanting ions into the buried oxide to form a doped glass layer between the buried oxide and the silicon layer.

Another object of the present invention is to provide a method of forming a SIMOX structure. The method may include providing a silicon substrate, forming a thin silicon layer over the doped oxide layer, and implanting carbon into the top silicon layer close to the silicon layer/buried oxide interface.

A low dislocation density may be formed in the top silicon layer of the semiconductor structure.

Further, the viscous temperature of the buried oxide layer may be reduced, thereby allowing easy slippage of silicon atoms and leading to a reduced dislocation density.

The present invention provides a technique to reduce the dislocation density for a SOI substrate prepared by oxygen ion implantation (SIMOX) through the implantation of boron (or phosphors) to form a buried boron silicate glass (BSG), or phosphorous silicate glass (PSG), or BPSG.

The present invention also provides a technique to reduce dislocation density for a SIMOX substrate by carbon implantation. Carbon implantation can fill the void generated in the top silicon layer, and prevent the out diffusion of boron and/or phosphorous dopants if so desired.

Other objects, advantages and salient features of the invention will become apparent from the following detailed description taken in conjunction with the annexed drawings, which disclose preferred embodiments of the invention.

### BRIEF DESCRIPTION OF THE DRAWINGS

The invention will be described in detail with reference to the following drawings in which like reference numerals refer to like elements and wherein:

FIG. 1 is a conventional SOI structure having a buried SiO₂ layer;

FIG. 2 is a conventional SOI structure having a top SiGe layer;

FIG. 3 is a conventional SOI structure having a buried BSG layer; and

FIG. 4 is an SOI structure according to the present invention.

### DETAILED DESCRIPTION OF PREFERRED EMBODIMENTS OF THE INVENTION

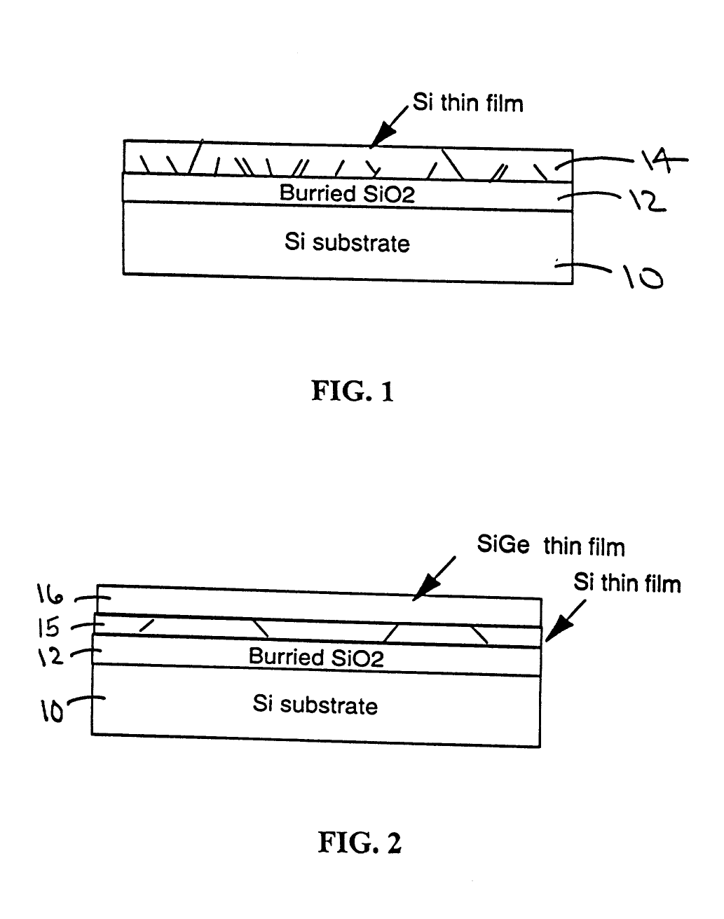

The present invention provides a unique structure by providing a doped glass layer buried underneath a silicon layer formed by ion implantation over a silicon substrate. This reduces the dislocation density of the top silicon layer and thus provides a better SOI substrate as compared with the prior art such as that shown in FIG. 1.

To assist the slippage of silicon atoms atop of the buried oxide layer, the re-floating (viscous) temperature of the buried oxide may be reduced. It is well known to one skilled in the art that boron silicate glass (BSG), phosphorous silicate glass (PSG) and boron phosphorous silicate glass (BPSG) have a much lower refloating temperature as compared with silicon dioxide. Depending on the boron or phosphorous concentration, the viscous temperature can go down to 900° C. or even 700° C. At such a low viscous temperature, buried BSG, PSG or BPSG will easily refloat such that the silicon relaxes to become a crystalline structure after a high temperature (i.e., 1100° C.) anneal.

BSG, PSG, or BPSG have been used for dielectric isolation by an oxide deposition atop of a silicon substrate. The formation of the buried BSG (or PSG or BPSG) layer underneath a crystalline silicon is rather straightforward. During the oxygen implantation, boron or phosphorus can be co-implanted with oxygen (or implanted after the oxygen) with desired concentration and distance. Since boron has a smaller atomic size compared to phosphors causing less damage to the silicon, it is preferable to use BSG as the buried oxide. Due to the lower viscous temperature of the BSG layer as compared to silicon dioxide, the defects generated by the high energy oxygen implantation in the silicon layer can easily relax to a perfect lattice structure at a high temperature anneal.

“Growth and Characterization of Low Dislocation Relaxed SiGe Alloys Grown on Silicon on Insulator (SOI) and Implanted SOI Substrates”, by Chu et al. (1996), the subject matter of which is incorporated herein by reference, discloses a method which utilizes the low viscous temperature of boron silicate glass (BSG) or phosphorous silicate glass (PSG). Based on the implantation of boron or phosphorous to the buried oxide, the reflow temperature has been reduced to 750° C. However, this work related to the growth of strain relaxed SiGe alloy on an extremely thin (˜100 Å) Si with a perfect crystalline structure. This kind of SOI substrate requires special preparation techniques such as bond and etch back, normally referred to as BESOI.

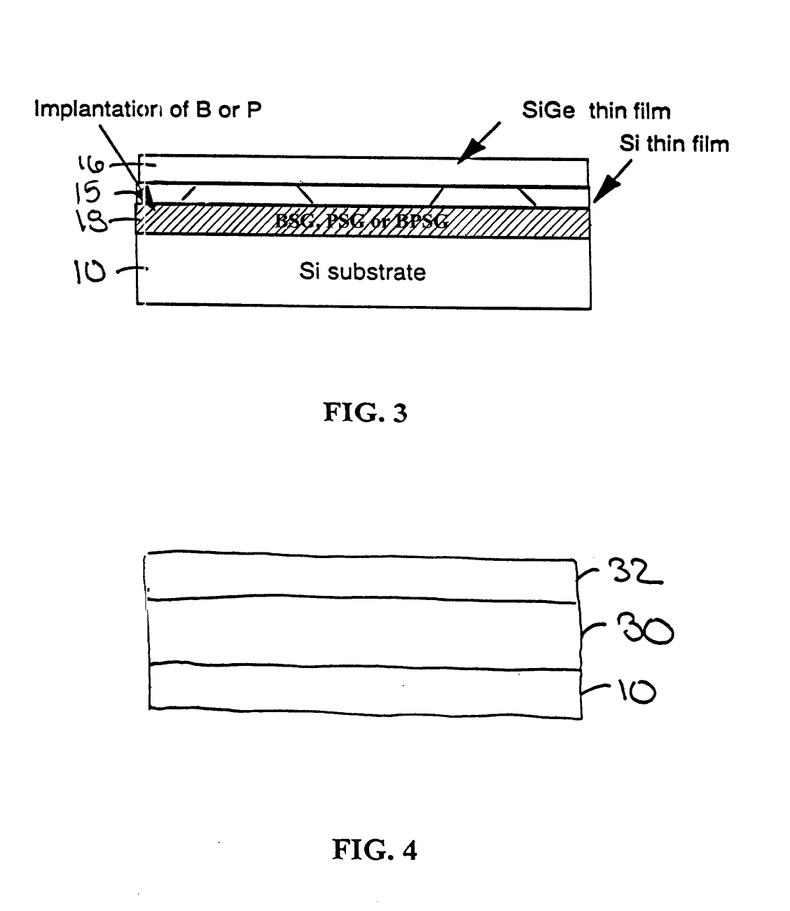

FIG. 3 shows a structure having a buried BSG (or PSG or BPSG) layer 18 formed on the silicon substrate 10. A thin silicon layer 15 is formed over the buried BSG layer 18 and an SiGe layer 16 is formed over the thin silicon layer 15. The lowered viscous temperature of the BSG layer 18 enables the transfer of strain from the SiGe layer 16 grown atop of the thin silicon layer 15 to the underneath thin silicon layer 15 due to the lattice relaxation. The BESOI substrate for this purpose assumes extremely low defect density on the top silicon layer prior to the strain transfer, and may become highly strained or even dislocated after the strain transfer. The BESOI substrates are also very expensive as compared to SIMOX wafers, so methods to reduce the defect density in SIMOX wafers are highly desirable.

FIG. 4 shows a unique and novel semiconductor substrate according to the present invention. This structure utilizes a BSG layer for a different purpose than that of the prior art. Accumulating strain from the SiGe layer atop of it will lead to dislocation generation in the extremely thin silicon layer if the strain exceeds a certain critical value as disclosed by prior art in FIG. 3. Instead, the silicon film in the present invention can be thicker than the prior art of FIG. 3, and kept strain and dislocation free upon a relatively high annealing temperature due to the doped glass. As shown, a silicon substrate 10 is initially provided in a conventional manner. A silicon layer 32 is formed over the doped glass 30, such as BSG, which is formed by ion implantation of oxygen and boron. Due to the low viscous temperature of the BSG layer 30 as compared to the silicon dioxide, the defects generated by the high energy oxygen implantation in the top silicon layer can be easily relaxed to a perfect lattice structure at a high temperature anneal. Thus, the application of the buried BSG layer 30 is unique in that it achieves a low dislocation density in the top silicon layer 32. This has not been accomplished by the prior art. Implantation of boron and oxygen reduces the dislocation density of the thin silicon layer 32. Experimental results have shown the dislocation density to be reduced to below 10³/cm².

Alternatively, the glass layer may comprise a PSG or BPSG layer rather than a BSG layer. A PSG layer may be formed by ion implantation of phosphorous and oxygen and a BPSG layer may be formed by ion implantation of boron, phosphorous and oxygen.

In a preferred embodiment, the top silicon film 32 is 0.1 microns to 0.2 microns thick, the BSG layer (or PSG layer or BPSG layer) 30 is 0.2 microns to 0.4 microns thick while the silicon substrate 10 is in the range of 200 to 500 microns thick.

The dopants in the buried BSG, PSG or BPSG layers may out-diffuse into the top silicon layer after thermal cycles are experienced in the standard CMOS or BiCMOS device fabrications. If the dopant has the same type as needed in the device (i.e., phosphorous for n-type layer), this out-diffusion will not cause device degradation. However, if such out-diffusion is detrimental to devices, a carbon implantation into the top silicon layer at the silicon/oxide interface will prevent the dopant out-diffusion with the added benefit of filling the voids in the silicon film.

While the invention has been described with reference to specific embodiments, the description of the specific embodiments is illustrative only and is not to be considered as limiting the scope of the invention. Various other modifications and changes may occur to those skilled in the art without departing from the spirit and scope of the invention.

What is claimed is:

1. A SIMOX semiconductor structure comprising:
a silicon substrate;
a doped glass layer formed on said silicon substrate by ion implantation; and
a silicon layer formed on said silicon substrate, wherein said ion implantation to form said doped glass layer reduces a dislocation density of said silicon layer.

2. The structure of claim 1, wherein said doped glass layer comprises boron silicate glass.

3. The structure of claim 2, wherein said doped glass layer is formed by ion implantation of oxygen and boron.

4. The structure of claim 1, wherein said doped glass layer comprises phosphorous silicate glass.

5. The structure of claim 4, wherein said doped glass layer is formed by ion implantation of phosphorous and oxygen.

6. The structure of claim 1, wherein said doped glass layer comprises boron phosphorous silicate glass.

7. The structure of claim 1, wherein said ion implantation reduces said dislocation density to below 10³/cm².

8. A method of forming a SIMOX semiconductor structure, the method comprising:
providing a silicon substrate;
forming a silicon layer over said silicon substrate; and
decreasing a dislocation density of said silicon layer by implanting ions into said silicon substrate to form a doped glass layer between said silicon substrate and said silicon layer.

9. The method of claim 8, wherein said doped glass layer comprises boron silicate glass.

10. The method of claim 9, wherein decreasing said dislocation density comprises implanting oxygen and boron ions into said silicon substrate.

11. The method of claim 8, wherein said glass layer comprises phosphorous silicate glass.

12. The method of claim 11, wherein decreasing said dislocation density comprises implanting phosphorous and oxygen ions into said silicon substrate.

13. The method of claim 8, wherein said glass layer comprises boron phosphorous silicate glass.

14. The method of claim 8, wherein said dislocation density is decreased to below 10³/cm².

15. The method of claim 8, further comprising implanting carbon into said silicon layer.

16. The method of claim 15, wherein the implanted carbon prevents dopant out-diffusion and fills voids in said silicon layer.

17. A method of forming a SIMOX semiconductor structure, the method comprising:
providing a silicon substrate;
forming a buried doped glass layer on said silicon substrate; and
implanting carbon to said structure.

18. The method of claim 17, wherein said carbon is implanted into said silicon layer.
